(19) United States
(12) Patent Application Publication
(10) Pub. No.: US 2026/0089947 A1
(43) Pub. Date: Mar. 26, 2026

(54) METHOD OF MANUFACTURING SEMICONDUCTOR DEVICE

(71) Applicant: SK hynix Inc., Icheon-si Gyeonggi-do (KR)

(72) Inventors: Hyun Kyu LEE, Icheon-si Gyeonggi-do (KR); Sun Kak HWANG, Icheon-si (KR); Dong Chul YOO, Icheon-si Gyeonggi-do (KR)

(73) Assignee: SK hynix Inc., Icheon-si Gyeonggi-do (KR)

(21) Appl. No.: 19/018,480

(22) Filed: Jan. 13, 2025

(30) Foreign Application Priority Data
Sep. 24, 2024 (KR) 10-2024-0128947

(51) Int. Cl. H10B 43/27; H10B 41/27

(52) U.S. Cl. CPC H10B 43/27; H10B 41/27

(57) ABSTRACT

A method of manufacturing a semiconductor device includes forming a stack; forming a channel hole in the stack; forming a preliminary channel layer in the channel hole; forming a capping layer on the preliminary channel layer, the capping layer having a first thickness within a first section of the capping layer and a second thickness greater than the first thickness within a second section of the capping layer; forming metal seeds in the capping layer; diffusing the metal seeds into the preliminary channel layer through the capping layer; and forming a channel layer by crystallizing the preliminary channel layer using the metal seeds.

### CROSS-REFERENCE TO RELATED APPLICATION

The present application claims priority under 35 U.S.C. § 119(a) to Korean Patent Application No. 10-2024-0128947 filed in the Korean Intellectual Property Office on Sep. 24, 2024, which application is incorporated herein by reference in its entirety.

### BACKGROUND

### 1. Technical Field

The present disclosure relates to an electronic device, including but not limited to a method of manufacturing a semiconductor device.

### 2. Related Art

Integration density of semiconductor devices is determined by an area occupied by a unit memory cell. As the improvements in the integration density of semiconductor devices in which a memory cell is formed in a single layer on a substrate reaches a limit, three-dimensional semiconductor devices in which memory cells are stacked on a substrate are under development. Various structures and manufacturing methods are being developed to improve operation reliability of semiconductor devices.

### SUMMARY

In an embodiment, a method of manufacturing a semiconductor device may include: forming a stack; forming a channel hole in the stack; forming a preliminary channel layer in the channel hole; forming a capping layer on the preliminary channel layer, the capping layer having a first thickness within a first section of the capping layer and a second thickness greater than the first thickness within a second section of the capping layer; forming metal seeds in the capping layer; diffusing the metal seeds into the preliminary channel layer through the capping layer; and forming a channel layer by crystallizing the preliminary channel layer using the metal seeds.

In an embodiment, a method of manufacturing a semiconductor device may include: forming a stack; forming an opening in the stack; forming an amorphous silicon layer in the opening; forming a capping layer on the amorphous silicon layer, the capping layer including a first section having a first thickness and a second section having a second thickness thicker than the first thickness; doping the capping layer with metal, including a first doping concentration difference between the first section and the second section; doping the amorphous silicon layer, including a second doping concentration difference between a third section and a fourth section by diffusing the metal through the capping layer, wherein the second doping concentration difference is smaller than the first doping concentration difference; and forming a polysilicon layer by crystallizing the amorphous silicon layer using the metal as a seed.

In an embodiment, a method of manufacturing a semiconductor device may include forming a preliminary channel layer in a hole in a stack; forming a capping layer on the preliminary channel layer, wherein the capping layer has a varying thickness; forming metal seeds in the capping layer; diffusing the metal seeds into the preliminary channel layer through the capping layer; and forming a channel layer by crystallizing the preliminary channel layer using the metal seeds.

### BRIEF DESCRIPTION OF THE DRAWINGS

FIG. 1 is a diagram illustrating the structure of a semiconductor device in accordance with an embodiment.

FIG. 2A to FIG. 2D are diagrams illustrating a semiconductor device formed utilizing a method of manufacturing a semiconductor device in accordance with an embodiment.

FIG. 3A to FIG. 3H are diagrams illustrating views of a semiconductor device formed utilizing a method of manufacturing a semiconductor device in accordance with an embodiment.

FIG. 4 is a diagram illustrating the structure of a semiconductor device in accordance with an embodiment.

FIG. 5 is a configuration diagram of a semiconductor device in accordance with an embodiment.

FIG. 6 is a configuration diagram of a semiconductor device in accordance with an embodiment.

### DETAILED DESCRIPTION

The cross-hatching throughout the figures illustrates corresponding or similar areas between the figures rather than indicating the materials associated with the areas.

Terms such as “vertical,” “above,” “below,” “over,” “on,” “inside,” “upper,” “uppermost,” “lower,” “lowermost,” “higher,” “high,” “column,” “row,” “level,” and other terms implying relative spatial relationship or orientation are utilized only for the purpose of ease of description or reference to a drawing and are not otherwise limiting.

When one element is identified as “connected” to another element, the elements may be connected directly or through an intervening element between the elements. When two elements are identified as “directly connected,” one element is directly connected to the other element without an intervening element between the two elements.

The present disclosure is directed to a method of manufacturing a semiconductor device having a stable structure and improved characteristics.

By stacking memory cells in three dimensions, the integration density of a semiconductor device may be improved. A semiconductor device having a stable structure and improved reliability may result.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

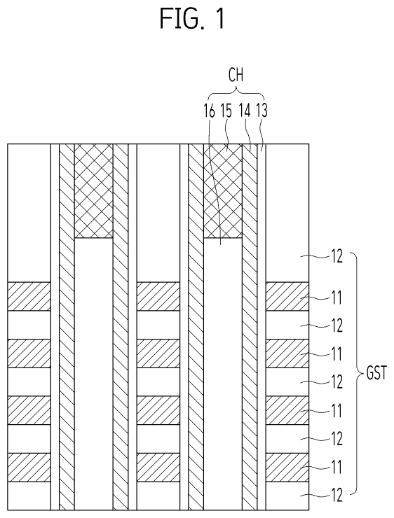

FIG. 1 is a diagram illustrating the structure of a semiconductor device in accordance with an embodiment.

Referring to FIG. 1, the semiconductor device includes a gate structure GST and a channel structure CH. The gate structure GST may include conductive layers 11 alternately stacked with insulating layers 12. The conductive layers 11 may be gate lines such as a drain select line, a source select line, and word lines. For example, at least one lowermost conductive layer 11 may be a source select line, at least one uppermost conductive layer 11 may be a drain select line, and the other conductive layers 11 may be word lines. The conductive layers 11 may include a conductive material such as polysilicon, tungsten, or molybdenum. The insulating layers 12 insulate the stacked conductive layers 11 from each other and may include an insulating material such as oxide, nitride, or air gap.

The channel structure CH extends through the gate structure GST. For example, the channel structure CH extends through the gate structure GST in a vertical direction with respect to the drawing. The channel structure CH includes a channel layer 14 and a channel pad 15, and at least one of a memory layer 13 and an insulating core 16.

The channel layer 14 may include a semiconductor material such as silicon or germanium and may have a polycrystalline structure. For example, the channel layer 14 may be a polysilicon layer and may include grains having a uniform size. A grain size of an upper end of the channel layer 14 may be substantially the same as a grain size of a lower end of the channel layer 14.

The insulating core 16 and the channel pad 15 is located inside the channel layer 14, and the channel pad 15 is located on the insulating core 16. The channel pad 15 is located inside the channel layer 14 and contacts inner walls of the channel layer 14. The memory layer 13 surrounds outer walls of the channel layer 14. The memory layer 13 includes at least one of a tunneling layer, a data storage layer, and a blocking layer. The data storage layer may include a floating gate, polysilicon, a charge trap material, nitride, a variable resistance material, and so forth.

In an embodiment, a source select transistor, a drain select transistor, or memory cells are located in regions where the channel structure CH intersects the conductive layers 11. For example, at least one source select transistor, a plurality of memory cells, and at least one drain select transistor are vertically stacked along the channel structure CH. As a result, the integration density of the semiconductor device may be increased or improved. When the channel layer 14 includes grains having uniform size, the memory cells have uniform characteristics regardless of stacking levels. The channel layer 14 may have a large grain size, and cell current may be improved. Accordingly, the operational characteristics of the semiconductor device may be improved.

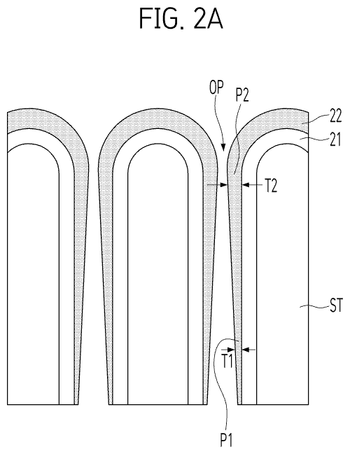

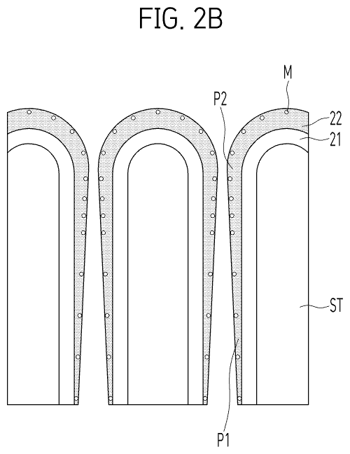

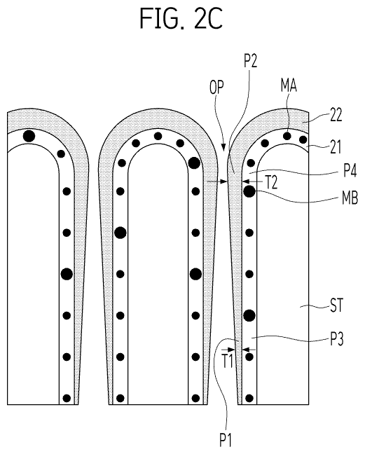

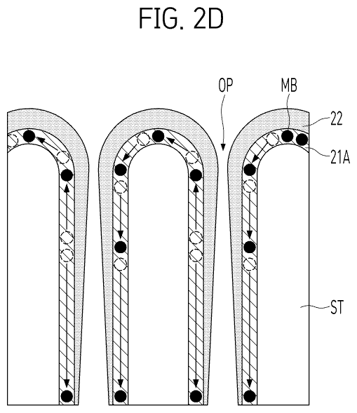

FIG. 2A to FIG. 2D are diagrams illustrating a semiconductor device formed utilizing a method of manufacturing a semiconductor device in accordance with an embodiment.

Referring to FIG. 2A, an opening OP may be formed in a stack ST. The opening OP may vertically extend through the stack ST. A plurality of openings OP are formed, and the plurality of openings OP may have a similar shape such as a circular shape, an elliptical shape, or a polygonal shape in, for example, an X-Y plane parallel to the bottom of FIG. 2A.

An amorphous layer 21 is formed in the opening OP. For example, the amorphous layer 21 may be an amorphous silicon layer. The amorphous layer 21 is formed along an outer surface of the stack ST and extends onto an upper surface of the stack ST.

A capping layer 22 is formed on the amorphous layer 21. The capping layer 22 is a layer that facilitates adjusting a diffusion rate of a dopant and has a varying thickness depending, for example, on vertical height or location. The capping layer 22 includes a lower or first section P1 having a first thickness T1 and an upper or second section P2 having a second thickness T2. The second thickness T2 is greater than the first thickness T1. The first section P1 is located at a lower level than the second section P2. The first section P1 is located near a lower end of the opening OP, and the second section P2 is located near an upper end of the opening OP. For example, the first thickness T1 may be 20 to 30 Å, and the second thickness T2 may be 40 to 50 Å.

The capping layer 22 may be formed using a deposition method. For example, the capping layer 22 may be formed by depositing a capping material by a method having poor step coverage. The capping layer 22 may be formed using a deposition method such as chemical vapor deposition (CVD) or atomic layer deposition (ALD). The capping material may be deposited in varying thicknesses due to the step coverage characteristic of the deposition method. The capping material may be deposited having a greater thickness at the upper or second section P2 than the thickness at the lower or first section P1. Accordingly, the capping layer 22 may have an overhang structure. The capping layer 22 may include an oxide. For example, the capping layer 22 may include silicon oxide. The capping layer 22 may be formed by deposition rather than an oxidation method, and the amorphous layer 21 may be prevented from being lost during the process of forming the capping layer 22.

Referring to FIG. 2B, the capping layer 22 is doped with a seed material M. The seed material M is used as a nucleus to crystallize the amorphous layer 21 and may include a metal such as nickel (Ni). For example, the capping layer 22 is doped with a precursor including metal by a CVD method. As the precursor is supplied, oxygen atoms are bonded to metal atoms on a surface of the capping layer 22, and any remaining components of the precursor may be volatilized. Through this process, the metal is adsorbed onto the surface of the capping layer 22. As the oxygen atoms of the capping layer 22 are bonded to the metal atoms, adsorption rate of the metal is increased compared to directly doping the amorphous layer 21 with metal.

Doping concentrations of the seed material M varies depending on the region of the capping layer 22. A doping concentration of a region near the upper end of the opening OP may be higher than a doping concentration of a region near the lower end of the opening OP. For example, a doping concentration of the second section P2 may be higher than the doping concentration of the first section P1, and the first section P1 may have a doping concentration different from the doping concentration of the second section P2. Compared to directly doping the amorphous layer 21 with the seed material M without a capping layer, the doping concentrations of both the first section P1 and the second section P2 are increased by doping the amorphous layer 21 with the seed material M through O-Ni bonds of the capping layer 22.

Referring to FIG. 2C, a metal seed is formed by annealing the capping layer 22 and is diffused into the amorphous layer 21 through the capping layer 22. Through this process, the amorphous layer 21 is doped with the metal seed at a uniform concentration. The metal seed may include a metal silicide MA and/or a metal silicide cluster MB.

The metal seed is formed by annealing the capping layer 22. For example, the capping layer 22 may be annealed at a temperature of 400 to 500° C. The seed material M may undergo a phase change during annealing. The seed material M reacts with silicon Si of the capping layer 22, and the metal silicide MA is formed. For example, nickel Ni reacts with silicon Si to form nickel silicide NiSi₂. The metal silicide MA may aggregate to form a metal silicide cluster MB. The capping layer 22 includes at least one of the seed material M, the metal silicide MA, and the metal silicide cluster MB.

The metal seed is diffused into the amorphous layer 21 by annealing the capping layer 22. The seed material M that does not undergo a phase change may be diffused into the amorphous layer 21, and at least one of the seed material M, the metal silicide MA, and the metal silicide cluster MB may be diffused into the amorphous layer 21. The diffused seed material M may undergo a phase change into the metal silicide MA, and diffused metal silicide MA may aggregate to form a metal silicide cluster MB. Through this process, the amorphous layer 21 is doped with the metal seed. Some of the seed material M, the metal silicide MA, and/or the metal silicide cluster MB may remain inside the capping layer 22.

The metal seed is diffused through the capping layer 22. When the capping layer 22 a different thickness at different levels or heights, diffusion rates of the metal seed are different depending on the level. In the second section P2 having a relatively large thickness T2, a path through which the metal seed passes is longer, thus, a proportion of the metal seed that ultimately reaches the amorphous layer 21 is lower and a diffusion rate is relatively low in the second section P2 compared to the first section P1. In the first section P1 having a relatively small thickness T1, a path through which the metal seed passes is shorter, thus, a proportion of the metal seed that ultimately reaches the amorphous layer 21 is higher and a diffusion rate is relatively high in the first section P1 compared to the second section P2.

The amorphous layer 21 includes a third section P3 near the first section P1 of the capping layer 22 and a fourth section P4 near the second section P2 of the capping layer 22. The third section P3 is doped through the first section P1, and the fourth section P4 is doped through the second section P2. Doping concentrations of the third section P3 and the fourth section P4 are determined according to a diffusion rate difference between the first section P1 and the second section P2.

By diffusing the metal seed through the first section P1 and the second section P2 at different thicknesses, a doping concentration difference may be reduced between the third section P3 and the fourth section P4. The capping layer 22 directly doped with the seed material M may have a larger doping concentration difference at different levels, while the amorphous layer 21 indirectly doped with the metal seed through the capping layer 22 has a smaller doping concentration difference at different levels. The first doping concentration difference between the first section P1 and the second section P2 is different from the second doping concentration difference between the third section P3 and the fourth section P4. Because the diffusion rate of the second section P2 is smaller than the diffusion rate of the first section P1, the second doping concentration difference is smaller than the first doping concentration difference. For example, the doping concentration of the second section P2 is higher than the doping concentration of the first section P1, and the third section P3 may have substantially the same doping concentration as the fourth section P4.

Referring to FIG. 2D, the amorphous layer 21 is annealed and crystallized, and a polycrystalline layer 21A is formed. For example, a polysilicon layer may be formed by annealing the amorphous silicon layer at a temperature of 600 to 800° C. During a crystallization process, the metal silicide MA and/or the metal silicide clusters MB are used as crystal nuclei, and the amorphous layer 21 may be crystallized by a metal induced crystallization (MIC) method.

According to the MIC method, nickel atoms generate crystallized silicon while moving to the amorphous layer. The nickel atoms have the lowest free energy at an interface between nickel silicide and amorphous silicon, and silicon atoms have the lowest free energy at an interface between nickel silicide and crystallized silicon. Accordingly, the nickel atoms move toward the amorphous silicon, and the silicon atoms move toward the crystallized silicon. The nickel atoms and the silicon atoms move in opposite directions, and a metal seed moves and crystallization occurs. By crystallizing the amorphous layer 21 using the metal seed as described, grains may grow to a greater size compared to an example where the metal seed is not used.

By crystallizing the amorphous layer 21 using the metal seed doped at a uniform concentration, the polycrystalline layer 21A includes grains having a larger size near the upper end of the opening OP but also near the lower end of the opening OP. When the amorphous layer is directly doped with metal without using the capping layer 22, the doping concentration difference depending on level may be larger. Due to a difference in doping environment, the doping concentration near the lower end of the opening OP are lower than the doping concentration near the upper end of the opening OP. As a result, grain sizes of the polycrystalline layer 21A are non-uniform. The grain size near the lower end of the opening is smaller than the grain size near the upper end of the opening. According to an embodiment of the present disclosure, the metal seed doped at the uniform concentration is used as a crystal nucleus, thus grains are grown to a uniform size in the polycrystalline layer 21A.

Although not illustrated in FIG. 2D, the capping layer 22 may be removed and the remainder of the opening OP may be filled.

According to the manufacturing method of an embodiment, the capping layer 22 is formed before the amorphous layer 21 is crystallized. The thickness of the capping layer 22 at each level may be determined based on doping concentration of the metal seed and the diffusion rate of the metal seed. When the thickness of the capping layer 22 is 20 Å or more, the doping concentration of the metal seed may be increased. When the thickness of the capping layer 22 is 50 Å or more, the metal seed may not reach the amorphous layer 21. Accordingly, the first thickness T1 may be 20 to 30 Å, and the second thickness T2 may be 40 to 50 Å. When the first thickness T1 is 20 to 30 Å, and the second thickness T2 is 40 to 50 Å, the amorphous layer 21 may be doped with the metal seed at a uniform concentration. Accordingly, the polycrystalline layer 21A may be formed having uniform grain size without varying based on level. The polycrystalline layer 21A may be used as a layer such as a channel layer, an electrode layer, or a contact layer.

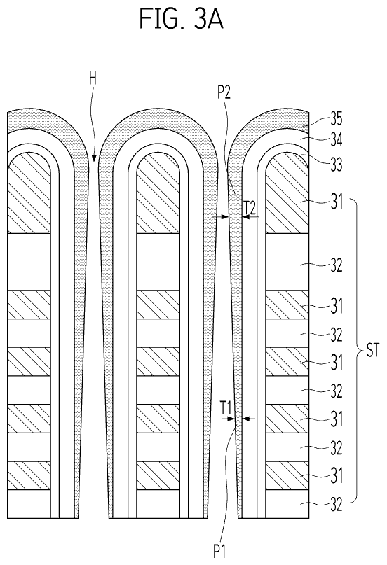

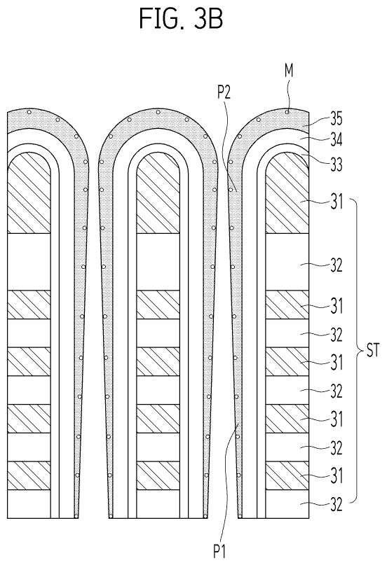

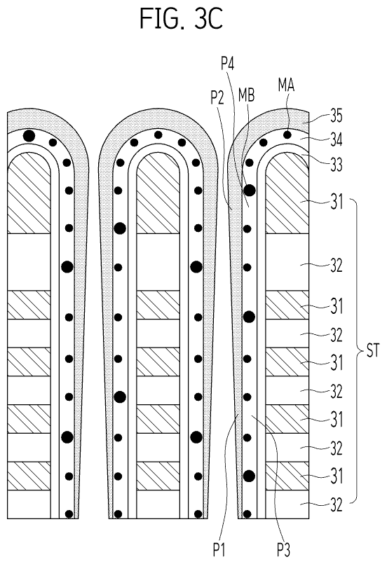

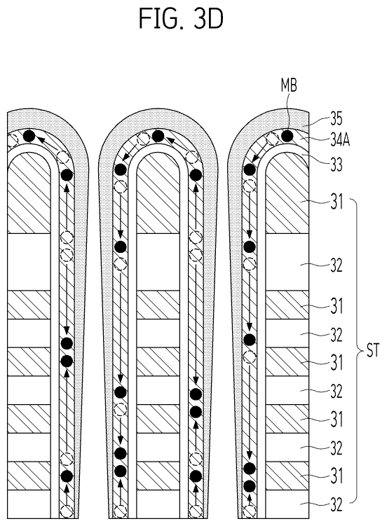

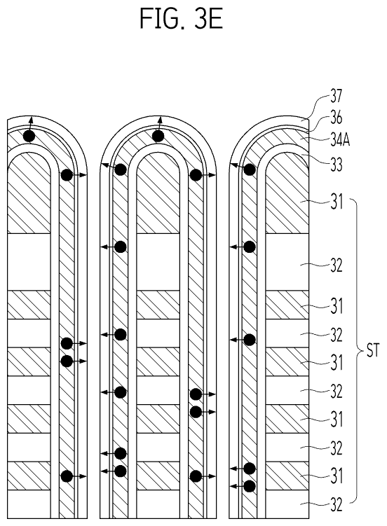

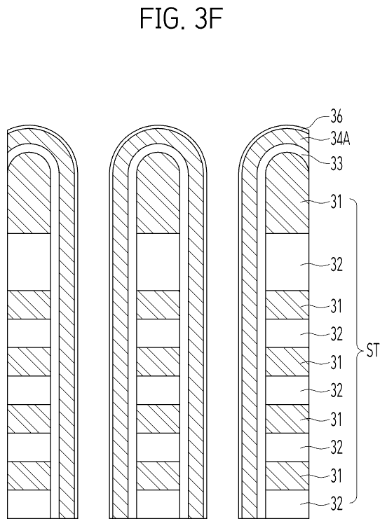

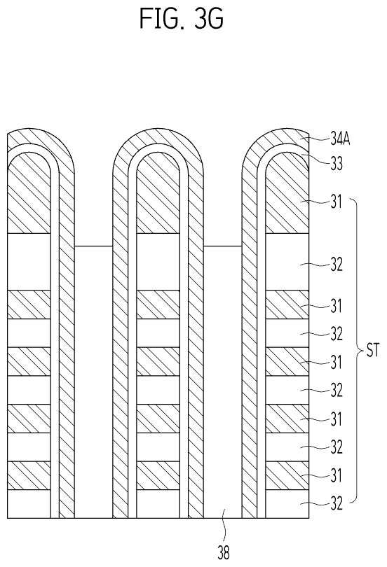

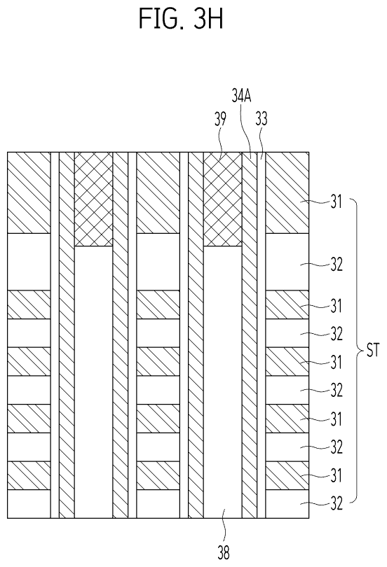

FIG. 3A to FIG. 3H are diagrams illustrating a semiconductor device formed utilizing a method of manufacturing a semiconductor device in accordance with an embodiment.

Referring to FIG. 3A, a stack ST is formed including first material layers 31 alternately stacked with second material layers 32. The first material layers 31 include a material having a high etching selectivity with respect to the etching selectivity of the second material layers 32. The first material layers 31 may be used to form gate lines. The first material layers 31 may include a sacrificial material such as nitride or a conductive material such as polysilicon. The second material layers 32 insulate the stacked gate lines from each other. The second material layers 32 may include an insulating material such as oxide, nitride, or air gap.

A hole is formed in the stack ST. For example, a channel hole H is formed in the stack ST. The channel hole H vertically extends through the stack ST. A plurality of channel holes H are formed, and the plurality of channel holes H may have a similar shape such as a circular shape, an elliptical shape, or a polygonal shape in, for example, an X-Y plane parallel to the bottom of FIG. 3A.

A memory layer 33 may be formed in the channel hole H and on the stack ST. The memory layer 33 is formed along an outer surface of the stack ST, and extends onto an upper surface of the stack ST. The memory layer 33 includes at least one of a blocking layer, a data storage layer, and a tunneling layer. For example, the blocking layer is formed on the stack ST, the data storage layer is formed on the blocking layer, and the tunneling layer is formed on the data storage layer.

A preliminary channel layer 34 may be formed on the memory layer 33 or in the channel hole H. The preliminary channel layer 34 is formed on the memory layer 33, and may be formed in the channel hole H and on the upper surface of the stack ST. The preliminary channel layer 34 is used to form a channel layer by utilizing a crystallization process and may include an amorphous silicon layer.

A capping layer 35 is formed on the preliminary channel layer 34. The capping layer 35 includes a first section P1 near a lower end of the channel hole H and a second section P2 near an upper end of the channel hole H. The first section P1 of the capping layer 35 has a different thickness than the thickness of the second section P2. The first section P1 has a first thickness T1, and the second section P2 has a second thickness T2 larger than the first thickness T1. T1 may be an average thickness, a maximum thickness, or a minimum thickness of the first section P1. T2 may be an average thickness, a maximum thickness, or a minimum thickness of the second section P2. The capping layer 35 may be formed using a deposition method having poor step coverage and may have an overhang structure. The capping layer 35 may include oxide. For example, the capping layer 22 may include silicon oxide.

Referring to FIG. 3B, the capping layer 35 is doped with a seed material M. The seed material M is used as a nucleus for crystallizing the preliminary channel layer 34 and may include metal such as nickel Ni. The capping layer 35 has different doping concentrations of the seed material M in the first section P1 than in the second section P2. The doping concentration of the second section P2 is higher than the doping concentration of the first section P1.

Referring to FIG. 3C, a metal seed is formed by annealing the capping layer 35 and is diffused into the preliminary channel layer 34 through the capping layer 35. The metal seed includes a metal silicide MA and/or a metal silicide cluster MB. The seed material M may be diffused into the preliminary channel layer 34 and the seed material M may react with the preliminary channel layer 34 to form the metal seed.

The metal seed is diffused through the capping layer 35. The preliminary channel layer 34 includes a third section P3 near the first section P1 and a fourth section P4 near the second section P2. The third section P3 is doped through the first section P1, and the fourth section P4 is doped through the second section P2. The first doping concentration difference between the first section P1 and the second section P2 is different from the second doping concentration difference between the third section P3 and the fourth section P4, which second doping concentration difference is smaller than the first doping concentration difference. The third section P3 and the fourth section P4 may have substantially the same doping concentration.

Referring to FIG. 3D, the preliminary channel layer 34 is annealed and crystallized, forming a channel layer 34A. During a crystallization process, the metal silicide MA and/or the metal silicide clusters MB may be used as crystal nuclei, and the preliminary channel layer 34 may be crystallized by the metal induced crystallization MIC method.

Because the preliminary channel layer 34 is crystallized using the metal seed doped at a uniform concentration, the channel layer 34A includes grains having a larger size near the upper end of the channel hole H and near the lower end of the channel hole H. The channel layer 34A is formed with grains grown to a uniform size near the upper end and the lower end of the channel layer 34A.

Referring to FIG. 3E, the capping layer 35 is removed. For example, the capping layer 35 may be removed using hydrogen fluoride (HF). The capping layer 35 including the metal seed is selectively removed.

A buffer layer 36 may be formed on the channel layer 34A. A getter layer 37 may be formed on the buffer layer 36 or on the channel layer 34A. The buffer layer 36 protects the channel layer 34A during a gettering process and includes a material having a high etching selectivity with respect to the etching selectivity of the getter layer 37. The buffer layer 36 includes a material having resistance to a chemical used when removing the getter layer 37. For example, the getter layer 37 may include nitride, polysilicon, and so forth, and the buffer layer 36 may include SiCN, SiCO, and so forth.

The metal seed in the channel layer 34A is diffused into the getter layer 37 by annealing the getter layer 37. The getter layer 37 including amorphous silicon is formed, and the amorphous silicon is crystallized into polysilicon by an annealing process.

Referring to FIG. 3F, the getter layer 37 is removed. For example, the getter layer 37 may be selectively etched by a wet etching method using phosphoric acid and so forth. During a process of removing the getter layer 37, the buffer layer 36 is exposed and protects the channel layer 34A.

A gettering process may be repeatedly performed. A getter layer may be formed on the channel layer 34A, the metal seed in the channel layer 34A may be diffused into the getter layer by performing an annealing process, and the getter layer may be removed. By repeating the gettering process, the metal seed in the channel layer 34A may be removed, and a concentration of the metal seed remaining in the channel layer 34A is reduced.

The buffer layer 36 is removed. For example, the buffer layer 36 may be oxidized using an oxidation process, and the oxidized buffer layer 36 may be removed using hydrogen fluoride (HF).

Referring to FIG. 3G, an insulating core 38 is formed in the remainder of the channel hole H. For example, an insulating layer may be formed to fill the channel hole H, and the insulating core 38 may be formed by etching back the insulating layer. For example, the insulating layer may be etched using a dry cleaning process.

While the insulating layer is etched, the channel layer 34A is exposed, and the upper end of the channel layer 34A may be damaged. When the channel layer 34A includes the metal seed, the metal seed reacts with the channel layer 34A in a high-temperature gettering process. As the metal silicide clusters increase in size or quantity, agglomeration of the channel layer 34A may be caused. The area where the agglomeration is generated may be damaged during the process of etching the insulating layer, and the channel layer 34A and the surrounding layers may be damaged. According to an embodiment of the present disclosure, a metal seed doping concentration at the upper end of the preliminary channel layer 34 is reduced, and a concentration of the metal seed remaining on an upper end of the channel layer 34A is reduced. Accordingly, agglomeration caused during the gettering process may be reduced, and damage to the channel layer 34A may be reduced.

Referring to FIG. 3H, a channel pad 39 is formed. For example, a conductive layer is formed on the insulating core 38, and the channel pad 39 is formed by planarizing the conductive layer until a surface of the stack ST is exposed. The channel pad 39 may include polysilicon.

When the first material layers 31 are sacrificial layers, the first material layers 31 are replaced with third material layers. The third material layers are used to form gate lines and may include metal such as tungsten or molybdenum. Through this process, a gate structure is formed including the third material layers alternately stacked with the second material layers 32. When the first material layers 31 are conductive layers, a process of replacing the first material layers with the third material layers need not be performed. The first material layers 31 may be used as gate lines, and the stack ST may be used as a gate structure.

According to an embodiment of the manufacturing method of the present disclosure, the channel layer 34A is formed using the metal seed as the crystal nucleus, thus the channel layer 34A have a large grain size. The preliminary channel layer 34 is doped with metal seed at a uniform concentration according to a thickness difference within the capping layer 35, and the channel layer 34A may be formed having a uniform grain size without a size difference at different levels. Accordingly, cell current may be improved. The metal seed in the channel layer 34A is removed by a gettering process, and damage to the channel layer 34A due to the metal seed may be reduced.

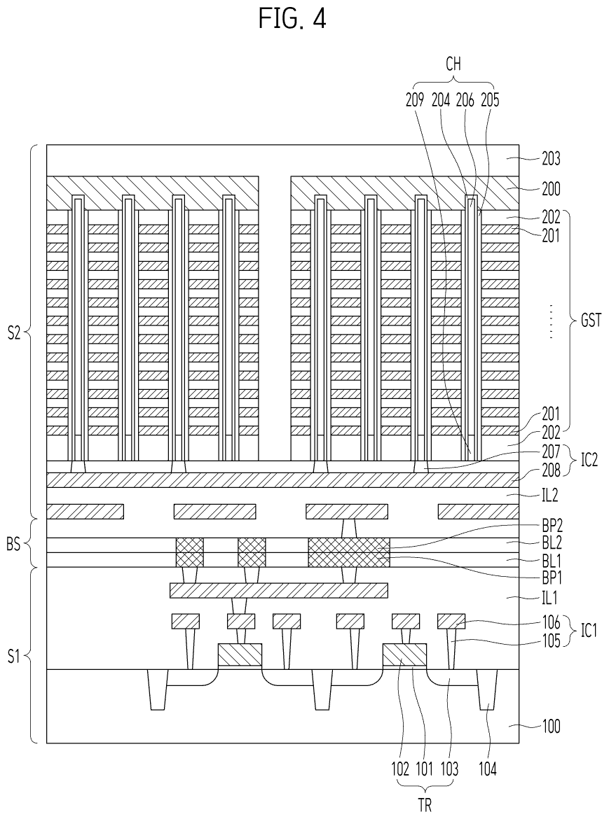

FIG. 4 is a diagram illustrating the structure of a semiconductor device in accordance with an embodiment.

Referring to FIG. 4, the semiconductor device includes a first semiconductor structure S1, a second semiconductor structure S2, and a bonding structure BS located between the first semiconductor structure S1 and the second semiconductor structure S2. The first semiconductor structure S1 and the second semiconductor structure S2 may be formed during separate processes and are electrically connected to each other by the bonding structure BS. For example, the first semiconductor structure S1 includes a peripheral circuit, and the second semiconductor structure S2 includes a memory cell array.

The first semiconductor structure S1 includes a substrate 100, a transistor TR, a first interconnection structure IC1, and a first interlayer insulating layer IL1. An active region includes an element isolation layer 104 in the substrate 100, and the transistor TR is located in the active region. The transistor TR includes a gate insulating layer 101, a gate electrode 102, and a junction 103. The transistor TR is included in the peripheral circuit PC.

The first interconnection structure IC1 is located in the first interlayer insulating layer IL1 and includes a via 105, a wiring line 106, and so forth. The first interconnection structure IC1 is electrically connected to the peripheral circuit PC and is electrically connected to the transistor TR.

The second semiconductor structure S2 includes a source structure 200, a gate structure GST, an insulating layer 203, a second interconnection structure IC2, and a second interlayer insulating layer IL2. The source structure 200 may be located above or below the gate structure GST. The source structure 200 may include a conductive material such as polysilicon or metal.

The gate structure GST includes conductive layers 201 alternately stacked with insulating layers 202 that are. The conductive layers 201 may be gate lines such as a source select line, a drain select line, and word lines. A channel structure CH extends through the gate structure GST and is connected to the source structure 200. The channel structure CH includes a channel layer 204, a channel pad 209, a memory layer 205, and an insulating core 206. The channel structure CH is formed utilizing the manufacturing method described with reference to FIG. 2A to FIG. 2D and FIG. 3A to FIG. 3H.

The second interconnection structure IC2 is located within the second interlayer insulating layer IL2 and includes a via 207, a wiring line 208, and so forth. The second interconnection structure IC2 is electrically connected to the channel structure CH, the gate structure GST, and so forth.

The bonding structure BS includes a first bonding layer BL1, a second bonding layer BL2, a first bonding pad BP1, and a second bonding pad BP2. The first bonding layer BL1 contacts the second bonding layer BL2, and the first bonding pad BP1 contacts the second bonding pad BP2. The first bonding layer BL1 and the second bonding layer BL2 may each include SiCN, tetra ethyl ortho silicate (TEOS), and so forth. The first bonding pad BP1 is electrically connected to the first interconnection structure IC1, and the second bonding pad BP2 is electrically connected to the second interconnection structure IC2. The memory cell array CA is electrically connected to the peripheral circuit PC through the first bonding pad BP1 and the second bonding pad BP2.

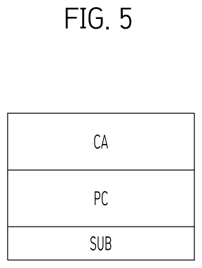

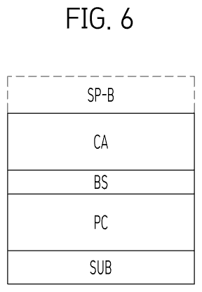

The structure and the manufacturing method according to the described embodiments may be applied to semiconductor devices of various structures. FIG. 5 and FIG. 6 illustrate configurations of a semiconductor device to which the embodiments are applicable.

FIG. 5 is a configuration diagram of a semiconductor device according to an embodiment of the present disclosure.

Referring to FIG. 5, the semiconductor device includes a substrate SUB, a peripheral circuit PC, and a memory cell array CA. The peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor as referenced in the periodic table. The group IV semiconductors may include single crystal silicon Si, polycrystalline silicon, germanium Ge, or silicon germanium SiGe. The group III-V compound semiconductors may include gallium arsenide GaAs, gallium nitride GaN, gallium phosphide GaP, gallium arsenide phosphide GaAsP, gallium indium arsenide phosphide GaInAsP, aluminum arsenide AlAs, aluminum gallium AlGa, indium phosphide InP, indium antimonide InSb, or indium gallium arsenide InGaAs. The group II-VI compound semiconductor may include zinc sulfide ZnS, zinc oxide ZnO, or cadmium sulfide CdS.

The substrate SUB includes a dielectric layer. The substrate SUB may be a silicon-on-insulator SOI substrate, a germanium-on-insulator GeOI substrate, or a glass substrate. The substrate SUB may include an organic material. In an embodiment, the substrate SUB may include graphene.

The substrate SUB may be a bulk wafer or an epitaxial layer grown using a selective epitaxial growth SEG method. The substrate SUB may be a layer formed using a metal induced lateral crystallization MILC method and may partially include a metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC is disposed between the substrate SUB and the memory cell array CA. The peripheral circuit PC includes a row decoder, a column decoder, a page buffer, a logic circuit, a control circuit, a sense amplifier, an input/output circuit, and so forth. In an embodiment, the peripheral circuit PC includes an NMOS transistor, a PMOS transistor, a resistor, a capacitor, and so forth. The peripheral circuit PC may include an interconnection structure. The interconnection structure includes a path for transferring an operation voltage and may include a contact plug, a line, and so forth.

The memory cell array CA includes memory cells. In an embodiment, the memory cell array CA includes memory strings connected between a source line and a bit line, and each memory string may include stacked memory cells. In an embodiment, the memory cell array CA includes memory cells connected between a word line and a bit line. The memory cell array CA includes an interconnection structure.

FIG. 6 is a configuration diagram of a semiconductor device according to an embodiment of the present disclosure.

Referring to FIG. 6, the semiconductor device includes a substrate SUB, a peripheral circuit PC, a bonding structure BS, and a memory cell array CA. The peripheral circuit PC and the memory cell array CA may be formed on separate substrates and bonded. The semiconductor device optionally includes a support base SP-B.

The substrate SUB is a support used during a process of forming the peripheral circuit PC. The support base SP-B is a support used during a process of forming the memory cell array CA. In an embodiment, after manufacturing a first wafer including the memory cell array CA and a second wafer including the peripheral circuit PC, the first wafer and the second wafer are electrically connected by the bonding structure BS. After bonding, at least a portion of the support base SP-B of the first wafer is removed. The support base SP-B may be completely removed or may partially remain on the memory cell array CA.

The support base SP-B may be a semiconductor substrate, an insulating substrate, a silicon-on-insulator (SOI) substrate, a germanium-on-insulator GeOI substrate, and so forth. The support base SP-B may be a bulk wafer, an epitaxial layer grown using a selective epitaxial growth SEG method, or a layer formed using a metal induced lateral crystallization (MILC) method. The support base SP-B may have a single crystalline, polycrystalline, or amorphous state. The support base SP-B may include an impurity of group II, group III, group IV, group V, or group VI.

The bonding structure BS connects the memory cell array CA and the peripheral circuit PC. In an embodiment, the memory cell array CA and the peripheral circuit PC are bonded using a wafer-on-wafer bonding method, a chip-on-wafer bonding method, a chip-on-chip bonding method, and so forth. The bonding structure BS includes a bonding pad, a bonding layer, a bonding interface, and so forth. The bonding pad may include a metal such as copper and aluminum, and/or an alloy. The bonding interface may include a non-metal-non-metal interface, a metal-metal interface, and so forth. The memory cell array CA and the peripheral circuit PC are electrically connected by the bonding structure BS.

An interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Contact plugs, lines, and so forth as formed on different wafers may be electrically connected without a separate bonding pad.

Other configurations may be similar to those described with reference to FIG. 5.

The semiconductor device may have a structure in which various elements of the embodiments described with reference to FIG. 5 and FIG. 6 are combined or may have a partially modified structure. In the embodiment described with reference to FIG. 5 and FIG. 6, positions of the memory cell array CA and the peripheral circuit PC may be changed. At least one memory cell array CA and/or at least one peripheral circuit PC may be bonded to the embodiment described with reference to FIG. 5 and FIG. 6. In an embodiment, some of the peripheral circuitry PC is disposed in the memory cell array CA.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

What is claimed is:

1. A method of manufacturing a semiconductor device, the method comprising:
forming a stack;
forming a channel hole in the stack;
forming a preliminary channel layer in the channel hole;
forming a capping layer on the preliminary channel layer, the capping layer having a first thickness within a first section of the capping layer and a second thickness thicker than the first thickness within a second section of the capping layer;
forming metal seeds in the capping layer;
diffusing the metal seeds into the preliminary channel layer through the capping layer; and
forming a channel layer by crystallizing the preliminary channel layer using the metal seeds.

2. The method of claim 1, wherein the capping layer has an overhang structure.

3. The method of claim 1, wherein forming metal seeds in the capping layer comprises:
doping a surface of the capping layer with a precursor including metal;
adsorbing the metal onto the surface of the capping layer; and
forming a metal silicide by annealing the capping layer.

4. The method of claim 3, wherein forming metal seeds in the capping layer further comprises forming a metal silicide cluster by agglomerating the metal silicide.

5. The method of claim 1, wherein the metal seed includes at least one of a metal silicide and a metal silicide cluster.

6. The method of claim 1, wherein, while diffusing the metal seeds, a metal seed diffusion rate at the second section is smaller than a metal seed diffusion rate at the first section.

7. The method of claim 1, further comprising removing the capping layer.

8. The method of claim 1, further comprising:
forming a getter layer on the channel layer;
diffusing the metal seeds into the getter layer; and
removing the getter layer.

9. The method of claim 1, further comprising:
forming a buffer layer on the channel layer;
forming a getter layer on the buffer layer;
diffusing the metal seeds into the getter layer; and
removing the getter layer.

10. The method of claim 1, further comprising:
forming an insulating core within the channel layer; and
forming a channel pad on the insulating core.

11. The method of claim 10, wherein forming the insulating core comprises:
forming an insulating layer to fill space within the channel layer; and
forming the insulating core by etching the insulating layer using a dry cleaning process, thereby exposing the channel layer.

12. A method of manufacturing a semiconductor device, the method comprising:
forming a stack;
forming an opening in the stack;
forming an amorphous silicon layer in the opening;
forming a capping layer on the amorphous silicon layer, the capping layer including a first section having a first thickness and a second section having a second thickness thicker than the first thickness;
doping the capping layer with metal, including a first doping concentration difference between the first section and the second section;
doping the amorphous silicon layer, including a second doping concentration difference between a third section and a fourth section by diffusing the metal through the capping layer, wherein the second doping concentration difference is smaller than the first doping concentration difference; and
forming a polysilicon layer by crystallizing the amorphous silicon layer using the metal as a seed.

13. The method of claim 12, wherein the third section is doped through the first section, and the fourth section is doped through the second section.

14. The method of claim 12, wherein, while doping the amorphous silicon layer, a metal diffusion rate of the second portion is smaller than a metal diffusion rate of the first section.

15. The method of claim 12, wherein a metal doping concentration of the second section is higher than a metal doping concentration of the first section; and
a metal doping concentration of the third section is substantially the same as a metal doping concentration of the fourth section.

16. The method of claim 12, further comprising forming at least one of a metal silicide and a metal silicide cluster by annealing the capping layer doped with the metal.

17. The method of claim 16, wherein, while forming the polysilicon layer, one of the metal silicide and the metal silicide cluster is used as a metal seed.

18. The method of claim 12, further comprising removing the capping layer.

19. The method of claim 12, further comprising:
forming a getter layer on the polysilicon layer;
diffusing the metal from the polysilicon layer to the getter layer; and
removing the getter layer.

20. A method comprising:
forming a preliminary channel layer in a hole in a stack;
forming a capping layer on the preliminary channel layer, wherein the capping layer has a varying thickness;
forming metal seeds in the capping layer;
diffusing the metal seeds into the preliminary channel layer through the capping layer; and
forming a channel layer by crystallizing the preliminary channel layer using the metal seeds.
